(19) United States
(12) Patent Application Publication
(10) Pub. No.: US 2026/0206149 A1
(43) Pub. Date: Jul. 16, 2026

(54) CASE FOR AN ELECTRONIC DEVICE, METHOD OF FABRICATION AND STORAGE DEVICE USING THE SAME

(71) Applicant: SK hynix Inc., Icheon-si (KR)

(72) Inventors: Jong Won KIM, Icheon-si (KR); Sun Kyu KONG, Icheon-si (KR); Gi Taek KIM, Icheon-si (KR); Dong Hae LEE, Icheon-si (KR); Byoung Ick JANG, Icheon-si (KR); Kyoung Soo CHO, Icheon-si (KR)

(21) Appl. No.: 19/374,501

(22) Filed: Oct. 30, 2025

(30) Foreign Application Priority Data
Jan. 16, 2025 (KR) 10-2025-0006787
May 12, 2025 (KR) 10-2025-0061240

(51) Int. Cl. H05K 5/00; H05K 5/02

(52) U.S. Cl. CPC H05K 5/0052; H05K 5/006; H05K 5/0217; H05K 5/0247

(57) ABSTRACT

An electronic device case may include a top case covering a front surface of a printed circuit board (PCB) on which electronic components may be mounted, and having first fastening members formed at respective corners; and a bottom case housing the PCB and covering a rear surface of the PCB, and having second fastening members formed at positions corresponding to the first fastening members. Each of the top and bottom cases may include a coating layer formed so as to entirely avoid a surface expected to contact between the first fastening members and the second fastening members.

### CROSS-REFERENCES TO RELATED APPLICATIONS

The present application claims priority under 35 U.S.C. §119(a) to Korean application numbers 10-2025-0006787, filed on January 16, 2025, and 10-2025-0061240, filed on May 12, 2025, in the Korean Intellectual Property Office, which are incorporated herein by reference in their entireties.

### BACKGROUND

### 1. Technical Field

Example embodiments relate to an electronic device, and more particularly, to a case for an electronic device, a method of fabricating the case, and a storage device using the case.

### Related Art

An electronic device may be manufactured by mounting electronic components on a printed circuit board (PCB) and then covering the PCB with a case. An electrostatic discharge (ESD) generated from a human body or other sources during using of the electronic device may flow into the electronic components inside the case through the PCB. Electrostatic discharge may cause malfunction or fatal defects in the electronic device. Therefore, there is a need to manufacture electronic devices and cases for the electronic devices while considering the potential for ESD.

### SUMMARY

According to example embodiments, there may be provided a case for an electronic device. The case for the electronic device may include a top case and a bottom case. The top case may be configured to cover a front surface of a printed circuit board (PCB) on which electronic components may be mounted. The top case may include first fastening members at respective corners. The bottom case may receive the PCB to cover a rear surface of the PCB. The bottom case may include second fastening members at positions corresponding to the first fastening members. Each of the top and bottom cases may include a coating layer except for areas of interface between the first fastening members and the second fastening members.

According to example embodiments, there may be provided a method of fabricating a case for an electronic device. In the method of fabricating the case for the electronic device, conductive material may be provided. A top case having first fastening members and a bottom case having second fastening members using the conductive material may be casted. A coating layer may be formed on each of the top and bottom cases including surfaces of the first and second fastening members. The coating layer formed on a surface expected to contact between the first and second fastening members may be removed from surfaces of first fastening members and the second fastening members in areas that contact each other.

According to example embodiments, there may be provided a storage device. The storage device may include a printed circuit board (PCB), a top case and a bottom case. The PCB may have electronic components, including a controller and a non-volatile memory device, mounted on a front surface of the PCB. The PCB may have fastening holes at respective corners. The top case may be configured to cover the front surface of the PCB. The top case may include first fastening members at positions corresponding to the fastening holes. The bottom case may receive the PCB to cover a rear surface of the PCB. The bottom case may include second fastening members at positions corresponding to the first fastening members. A coating layer is disposed on surfaces of each of the top case and the bottom case, except on surfaces in contact between the first fastening members and the second fastening members.

According to example embodiments, electrostatic discharge introduced into the case of the electronic device may be guided to a grounding path without flowing into the electronic components, thereby protecting the electronic device from ESD.

### BRIEF DESCRIPTION OF THE DRAWINGS

The above and another aspects, features and advantages of the subject matter of the present disclosure will be more easily understood from the following detailed description taken in conjunction with the accompanying drawings, in which:

FIG. 1 is an exploded perspective view illustrating an electronic device case in accordance with example embodiments of the disclosure;

FIGS. 2A to 2C are views illustrating a top case of an electronic device case in accordance with example embodiments of the disclosure;

FIGS. 3A to 3C are views illustrating a bottom case of an electronic device case in accordance with example embodiments of the disclosure;

FIG. 4 is a flowchart illustrating a method of fabricating an electronic device case in accordance with example embodiments of the disclosure;

FIGS. 5A and 5B are views illustrating a method of manufacturing fastening members of an electronic device case in accordance with example embodiments of the disclosure;

FIG. 6 is a view illustrating an effective contact area according to a method of manufacturing fastening members of an electronic device case in accordance with example embodiments of the disclosure;

FIG. 7 is an exploded perspective view illustrating a storage device in accordance with example embodiments of the disclosure; and

FIG. 8 is a partial cross-sectional view illustrating a storage device in accordance with example embodiments of the disclosure.

### DETAILED DESCRIPTION

Example embodiments of the present disclosure will now be described in detail with reference to the accompanying drawings.

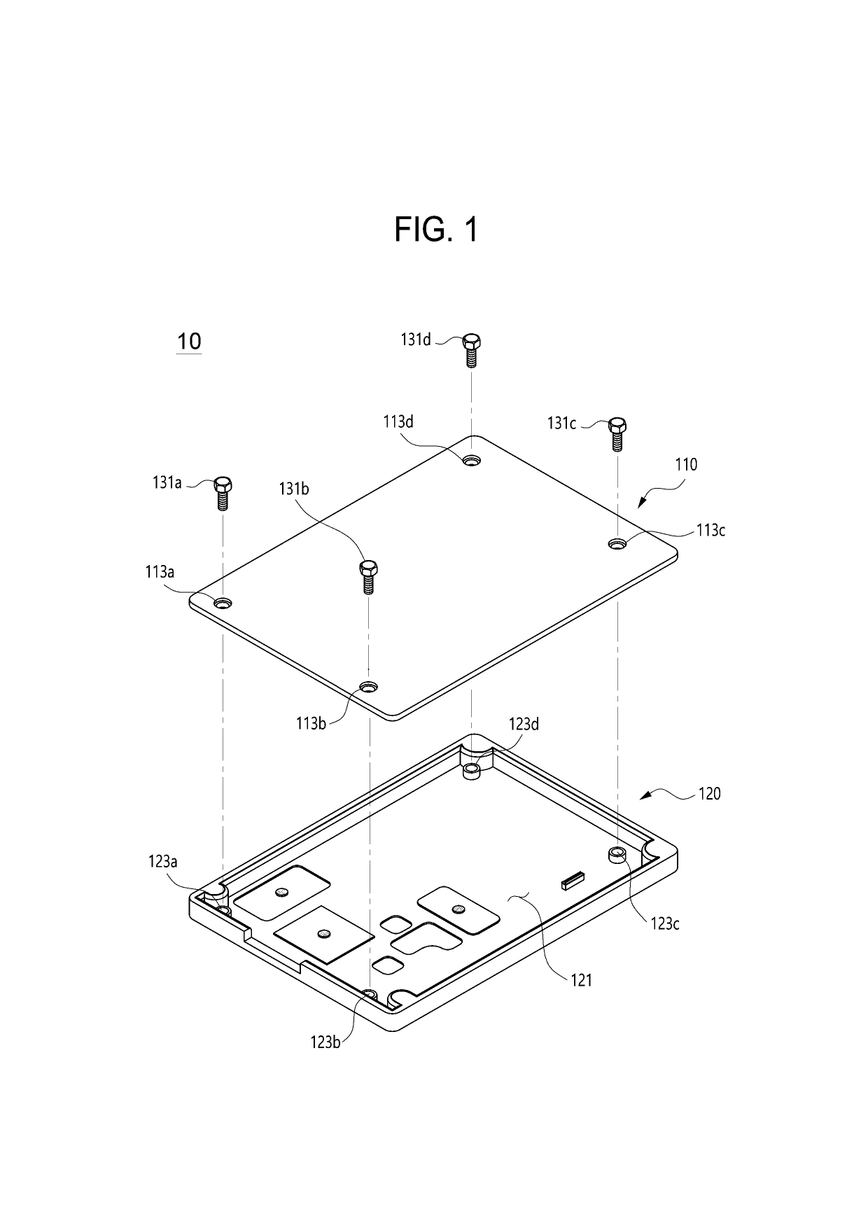

FIG. 1 is an exploded perspective view illustrating an electronic device case in accordance with example embodiments of the disclosure.

Referring to FIG. 1, an electronic device case 10 may include a top case 110 and a bottom case 120. A PCB (not shown) on which electronic components may be mounted may be accommodated in a receiving space 121 inside the bottom case 120. The bottom case 120 may cover a rear surface of the PCB. The top case 110 may be coupled to the bottom case 120 to cover a front surface of the PCB.

The top case 110 may have an overall rectangular plate shape and may form first fastening members 113a, 113b, 113c and 113d at respective corners of the top case 110. The bottom case 120 may have an overall rectangular volume shape and may form second fastening members 123a, 123b, 123c, and 123d at respective corners of the bottom case 120.

The electronic device case 10 may be assembled by fastening screws 131a, 131b, 131c and 131d through the first fastening members 113a, 113b, 113c and 113d and the second fastening members 123a, 123b, 123c and 123d, thereby coupling the top case 110 and the bottom case 120.

In example embodiments, the first fastening members 113a, 113b, 113c and 113d and the second fastening members 123a, 123b, 123c and 123d may be configured in the form of bosses and may be formed of a conductive material such as a metal.

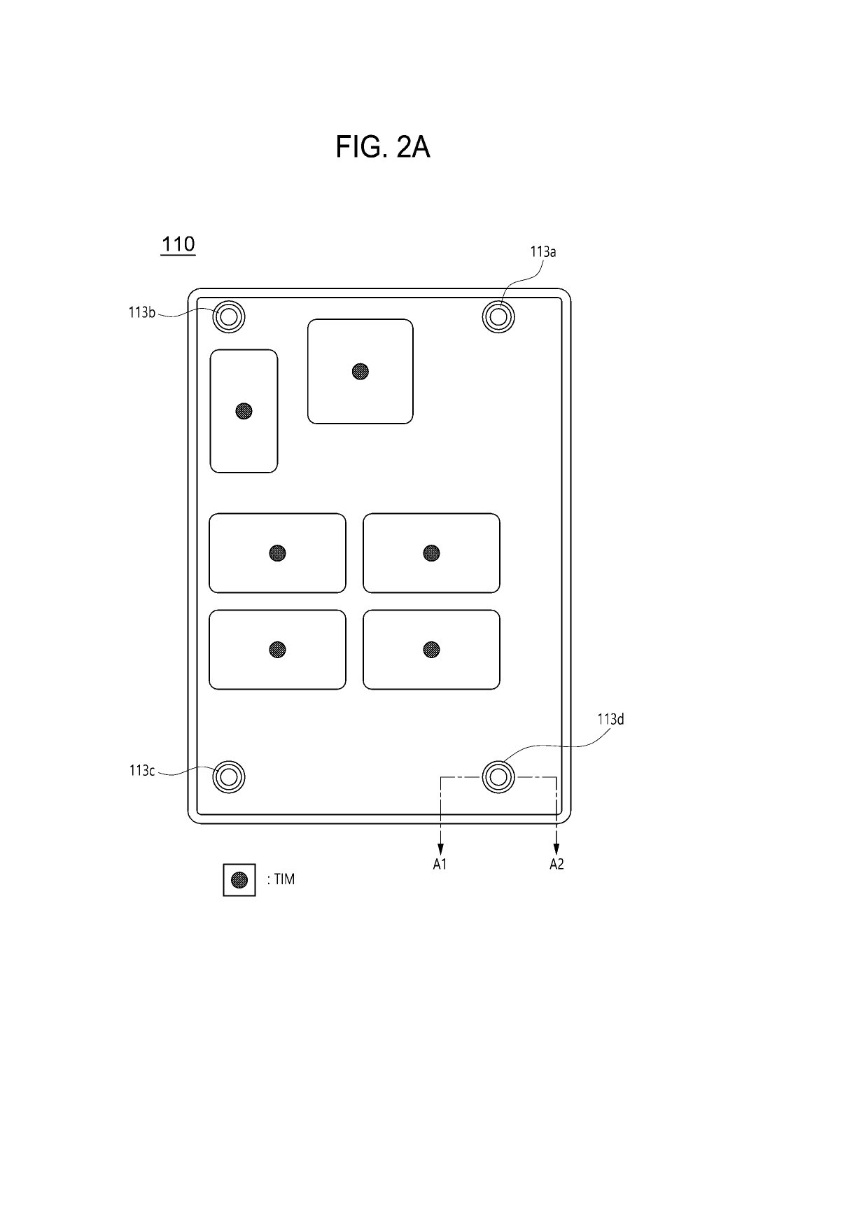

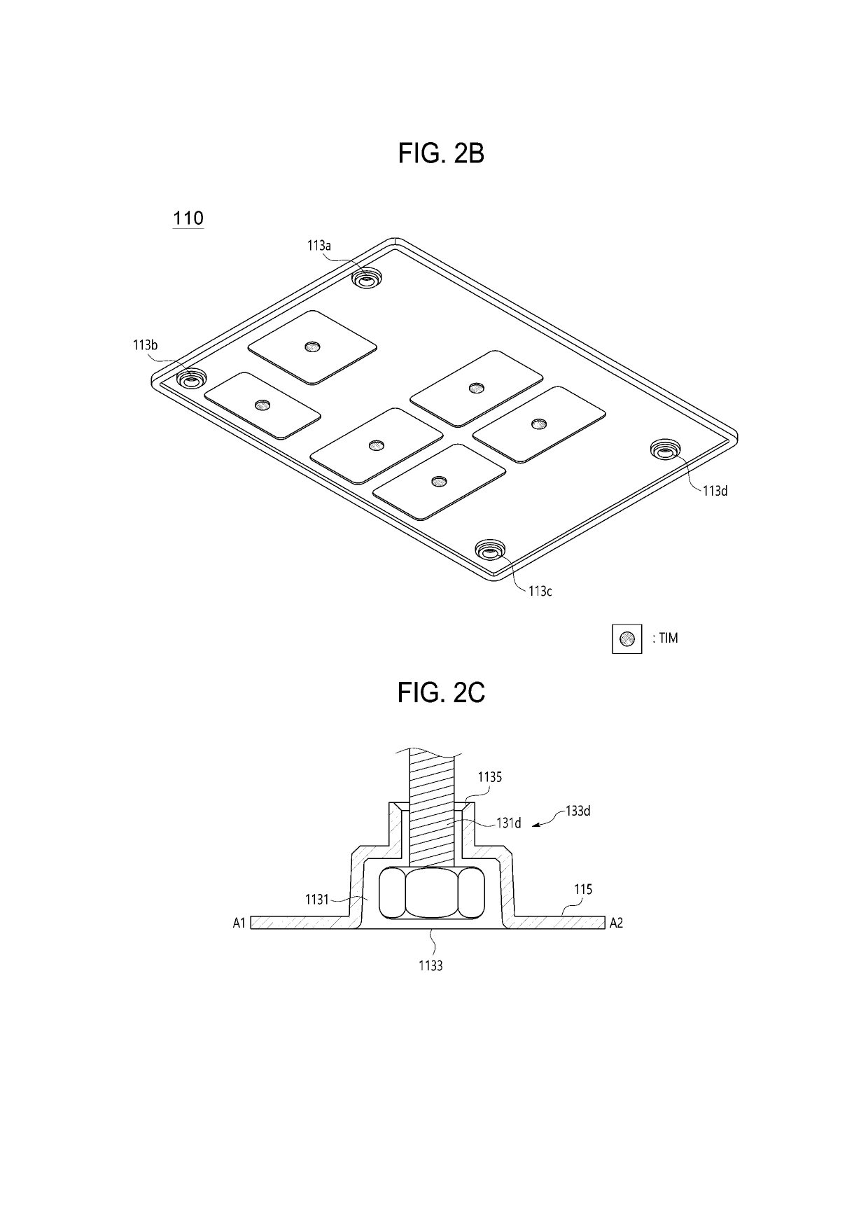

FIGS. 2A to 2C are views illustrating a top case of an electronic device case in accordance with example embodiments of the disclosure.

Referring to FIGS. 2A and 2B, first fastening members 113a, 113b, 113c and 113d may be formed at the respective corners of top case 110 in plan and perspective views. The first fastening members 113a, 113b, 113c and 113d may protrude toward the bottom case 120, that is, toward the front surface of the PCB to be covered by the top case 110.

A thermal interface material (TIM) pad may be attached to an inner surface of the top case 110, where the inner surface faces the front surface of the PCB.

FIG. 2C is a partial cross-sectional view of the top case 110 taken along a line A1-A2 of FIG. 2A to include the first fastening member 113d.

Referring to FIG. 2C, the first fastening member 113d may be formed by the top case 110 to include a hollow body 1131. One end of the hollow body 1131 may include a screw inlet hole 1133 into which a screw 131d may be inserted from outside of the top case 110. The other end of the hollow body 1131 may include a screw outlet hole 1135 formed in the top case 110 that may act as a guide, from the first fastening member 113d to a second fastening member 123d, for the screw 131d inserted through the screw inlet hole 1133 to the second fastening member 123d of a bottom case 120.

The plurality of first fastening members 113a, 113b, 113c and 113d may have the same structure. A coating layer 115, which includes a protective agent that inhibits oxidation of the top case 110, may be formed on surfaces around of the first fastening members 113a, 113b, 113c and 113d.

In more detail, in the first fastening members 113a, 113b, 113c and 113d, the coating layer 115 is not applied to surfaces of the top case 110 that may come into contact with any second fastening members and the bottom case 120. For example, the coating layer 115 is not applied to a contact-expected surface, which may be a surface of the screw outlet hole 1135 that could expose the hollow body 1131. The hollow body 1131 common to a side of the screw outlet hole 1135 may contact the second fastening members 123a, 123b, 123c and 123d of the bottom case 120.

That is, in example embodiments, the coating layer 115 may be applied to the top case 110 to avoid the screw outlet hole 1135 of the first fastening members 113a, 113b, 113c and 113d.

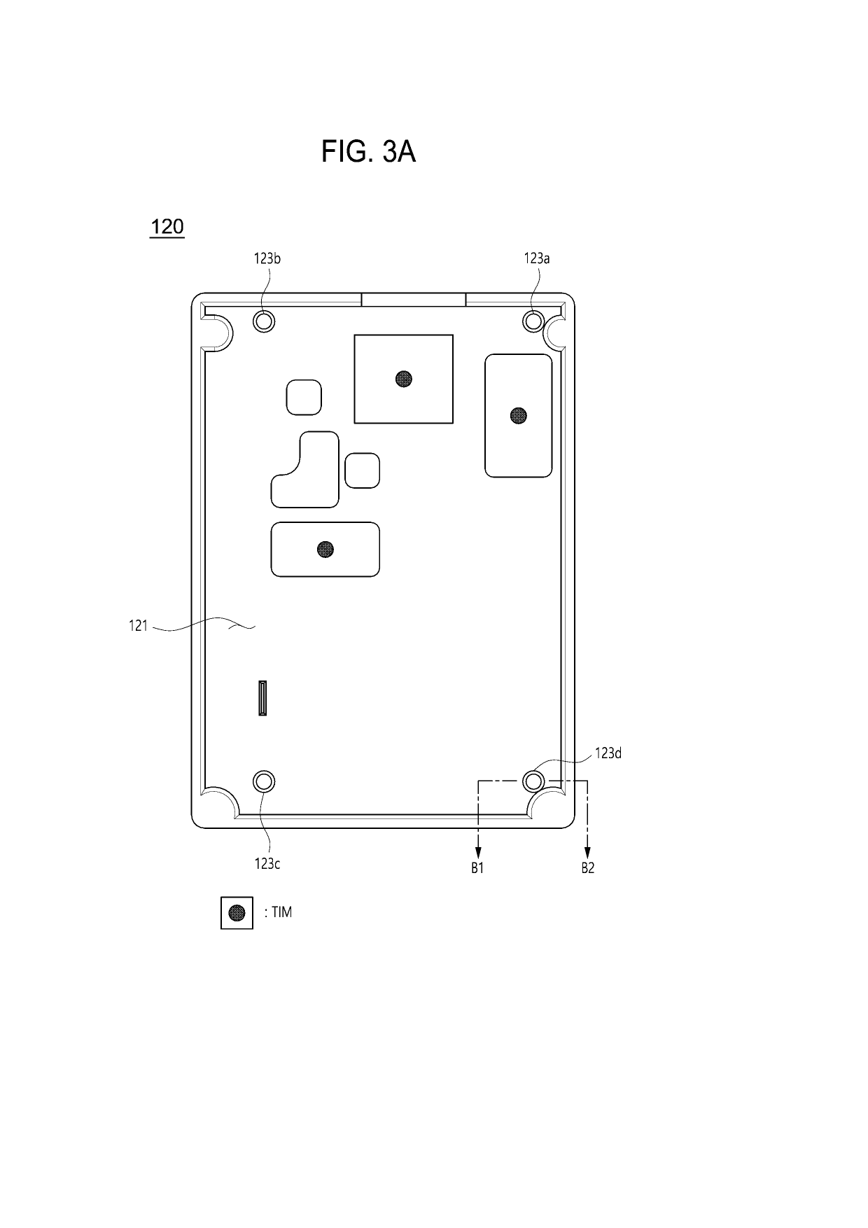

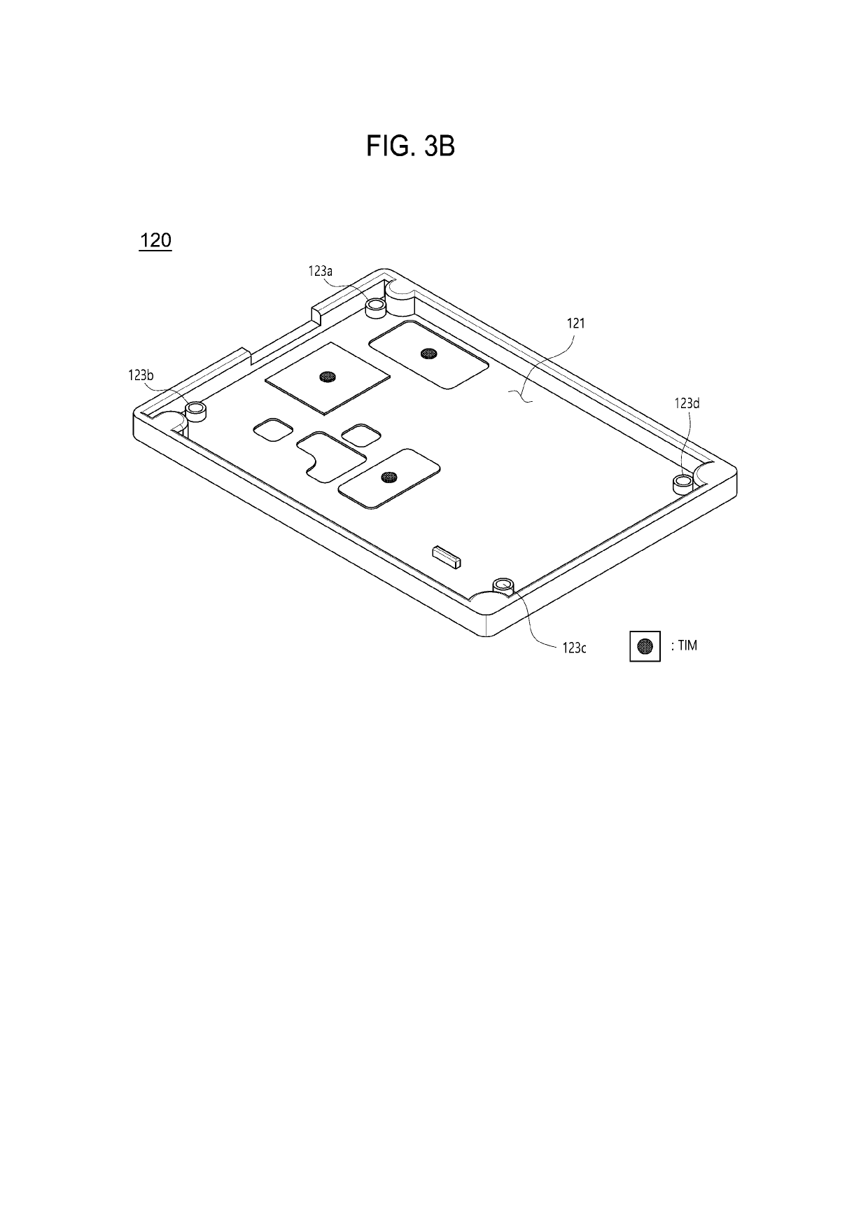

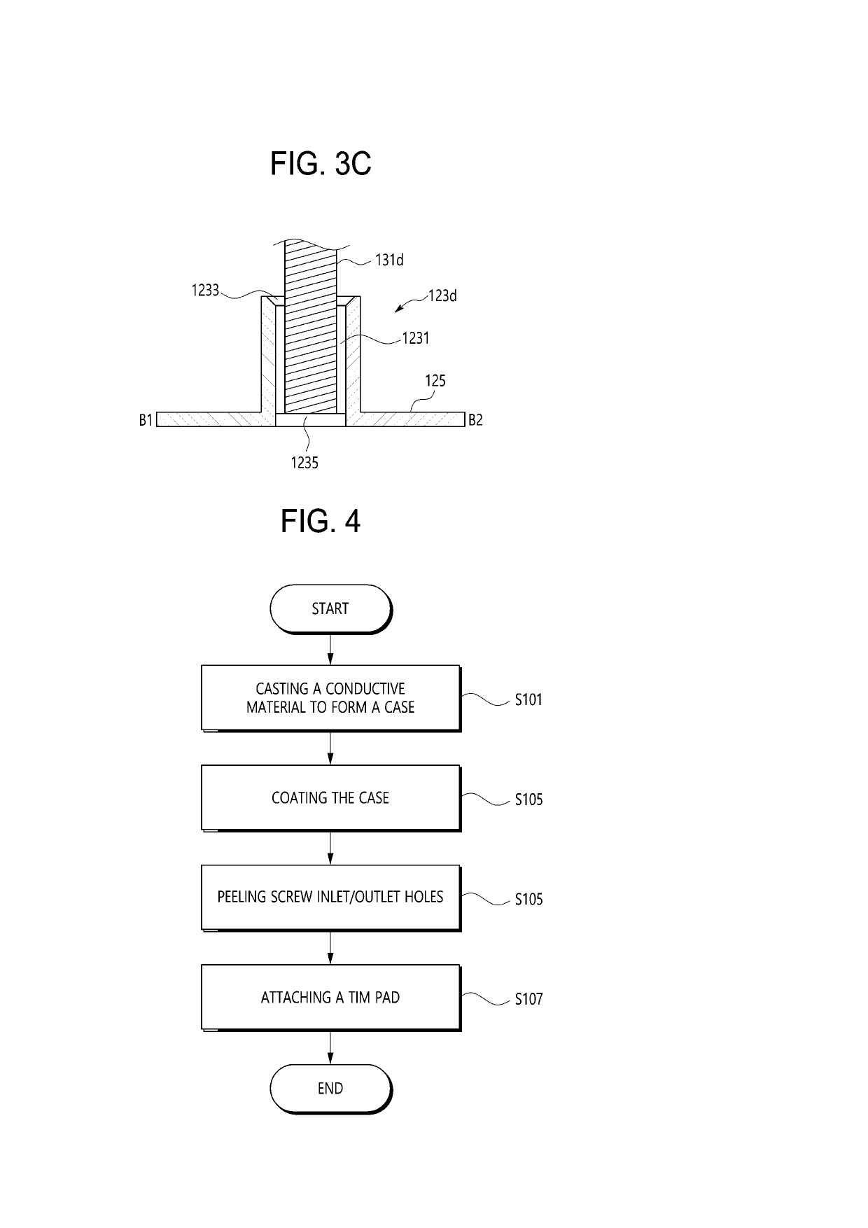

FIGS. 3A to 3C are views illustrating a bottom case of an electronic device case in accordance with example embodiments of the disclosure.

Referring to FIGS. 3A and 3B, a bottom case 120 may include second fastening members 123a, 123b, 123c and 123d protruding from an inner surface of the bottom case 120 to be fastened to a top case 110.

A thermal interface material (TIM) pad may be attached to the inner surface of the bottom case 120.

FIG. 3C is a partial cross-sectional view of the bottom case 120 taken along line B1-B2 of FIG. 3A to include the second fastening member 123d.

The second fastening member 123d may be formed by bottom case 120 to include a hollow body 1231. One end of the hollow body 1231 may include a screw inlet hole 1233 into which a screw 131d guided by the first fastening member 113d of the top case 110 may be inserted. Optionally, a screw seating surface 1235, on which the screw 131d inserted through the screw inlet hole 1233 is seated, can be disposed at the other end of the hollow body 1231.

The plurality of second fastening members 123a, 123b, 123c and 123d may have the same structure. A coating layer 125, which includes a protective agent that inhibits oxidation of the bottom case 120, may be formed on surfaces around of the second fastening members 123a, 123b, 123c and 123d.

In more detail, in the second fastening members 123a, 123b, 123c and 123d, the coating layer 125 is not applied to surfaces of the bottom case 120 that may come into contact with any first fastening members and the top case 110. For example, the coating layer 125 is not applied to a contact-expected surface, which may be a surface of the screw inlet hole 1233 that could expose the hollow body 1231. The hollow body 1231 common to a side of the screw inlet hole 1233 may contact the first fastening members 113a, 113b, 113c and 113d of the top case 110.

That is, in example embodiments, the coating layer 125 applied to the bottom case 120 avoids the screw inlet hole 1233 of the second fastening members 123a, 123b, 123c and 123d.

Accordingly, the portion of hollow body 1131 exposed by the screw outlet hole 1135 at one end of the top case 110 and the hollow body 1231 exposed by the screw inlet hole 1233 side of the bottom case 120 may connect to each at an interface absent of the coating layers 115 and 125.

In example embodiments, the top case 110 and the bottom case 120 may be formed by casting the cases with a conductive material to respectively include first fastening members 113a, 113b, 113c, 113d and second fastening members 123a, 123b, 123c, 123d in predesigned shapes and sizes. Next, coating layers 115, 125 are applied, and then portions of the coating layers 115, 125 are peeled away around the screw outlet holes 1135 of the first fastening members 113a, 113b, 113c, 113d and around the screw inlet holes 1233 of the second fastening members 123a, 123b, 123c, 123d.

When peeling off the coating layers 115, 125 around the screw outlet holes 1135 and around the screw inlet holes 1233, the diameter of the peeled area can be set to exceed the diameter of the screw outlet hole 1135 and the screw inlet hole 1233. As a result, it is possible to prevent the coating layers 115, 125 from remaining on the surfaces forming the hollow body 1131 around the screw outlet hole 1135 and the surfaces forming the hollow body 1231 around the screw inlet hole 1233.

FIG. 4 is a flowchart illustrating a method of fabricating an electronic device case in accordance with example embodiments of the disclosure.

Referring to FIGS. 1 to 4, a conductive material, for example, a material including metal, may be prepared for use in manufacturing electronic device case 10, and top case 110 and bottom case 120 may be formed respectively by casting the material (S101).

The cast top case 110 and bottom case 120 may respectively include at least the first fastening members 113a, 113b, 113c and 113d, and the second fastening members 123a, 123b, 123c and 123d.

Each of the top case 110 and the bottom case 120 may be entirely coated respectively with an insulating coating layer 115 and 125 (S103). In this process, the first fastening members 113a, 113b, 113c and 113d and the second fastening members 123a, 123b, 123c and 123d may also be coated with the coating layers 115 and 125.

To form an electrostatic discharge path in the electronic device case 10, the coating layers 115 and 125 formed on the contact surfaces of the first fastening members 113a, 113b, 113c and 113d and the second fastening members 123a, 123b, 123c and 123d, that is, on the screw outlet holes 1135 and screw inlet holes 1233, may be peeled away (S105). That is, the coating layers 115 and 125 may be disposed on the surfaces of the top case 110 and the bottom case 120 to avoid the contact-expected surfaces of the first and second fastening members.

After removing the coating layers 115 and 125, at least one thermal interface material (TIM) pad may be attached to designated locations of the top case 110 and the bottom case 120 (S107). The thermal interface material (TIM) may be configured to cool or dissipate heat generated from the electronic components formed on the PCB mounted in the electronic device case 10.

After completion of manufacturing the electronic device case 10, a PCB on which electronic components are mounted may be received in the electronic device case 10. Electrostatic charge that flows to the electronic device case 10 may be discharged through grounding terminals of the PCB connected between the screw outlet holes 1135 of the first fastening members and the screw inlet holes 1233 of the second fastening members.

The PCB received in the electronic device case 10 may include fastening holes at positions corresponding to the first fastening members 113a, 113b, 113c and 113d of the top case 110 and the second fastening members 123a, 123b, 123c and 123d of the bottom case 120. Grounding terminals surrounding the fastening holes may be formed around the PCB fastening holes.

A target PCB may be mounted so that the second fastening members 123a, 123b, 123c and 123d of the bottom case 120 may be exposed through the fastening holes of the PCB. The top case 110 may be arranged such that the first fastening members 113a, 113b, 113c and 113d may contact the second fastening members 123a, 123b, 123c and 123d of the bottom case 120, and screws 131a, 131b, 131c, and 131d may be fastened through the first and second fastening members.

In example embodiments, surfaces of the hollow body 1131 at the screw outlet hole 1135 of the first fastening members and surfaces of the hollow body 1231 at the screw inlet hole 1233 of the second fastening members may have entirely exposed conductive metal material that is not shielded by the coating layers 115 and 125. As a result, the conductive bodies of the first and second fastening members may improve contact properties with the grounding terminals formed around the fastening holes of the PCB.

The electrostatic discharge introduced from the outside of the electronic device case 10 may be quickly discharged from the case through the grounding terminals around the fastening holes of the PCB, thereby preventing the electrostatic charge from being introduced into the electronic components formed on the PCB.

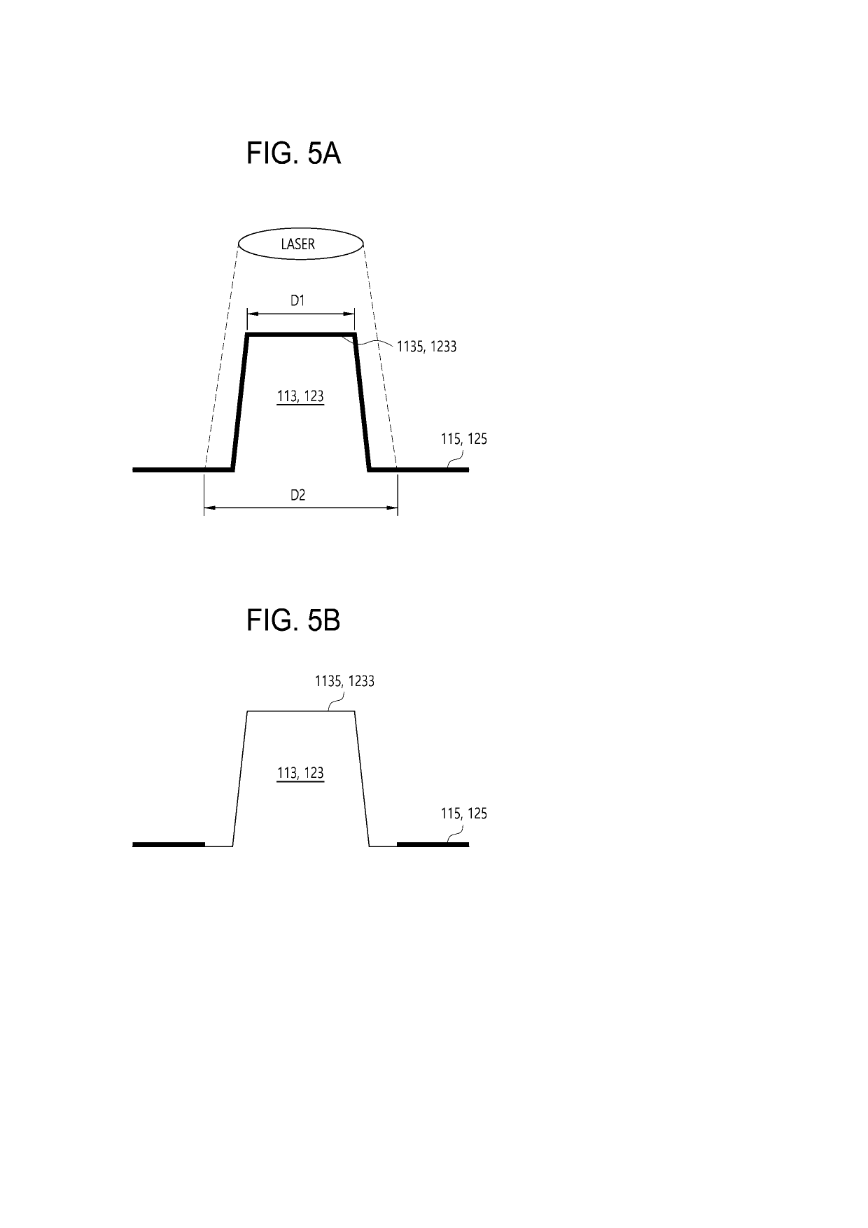

FIGS. 5A and 5B are views illustrating a method of manufacturing fastening members of an electronic device case in accordance with example embodiments of the disclosure.

For convenience of explanation, screw outlet holes 1135 of first fastening members 113a, 113b, 113c and 113d (collectively referred to as 113), and the screw inlet hole 1233 of the second fastening members 123a, 123b, 123c and 123d (collectively referred to as 123), will be collectively referred to as contact holes.

The coating layers 115 and 125 common to the contact holes 1135 and 1233 of the first and second fastening members 113 and 123, respectively, may be removed by, for example, laser processing.

When removing the coating layers 115 and 125 around the contact holes 1135 and 1233 using a laser, a peeling target diameter D2 may be set to be greater than a diameter D1 of the contact holes 1135 and 1233. In an example, the peeling target diameter D2 may be about 120% to about 130% of the first diameter D1 of the contact holes.

Accordingly, the coating layers 115 and 125 around the contact holes 1135 and 1233 may be entirely removed with sufficient margin for contact between the first and second fastening members.

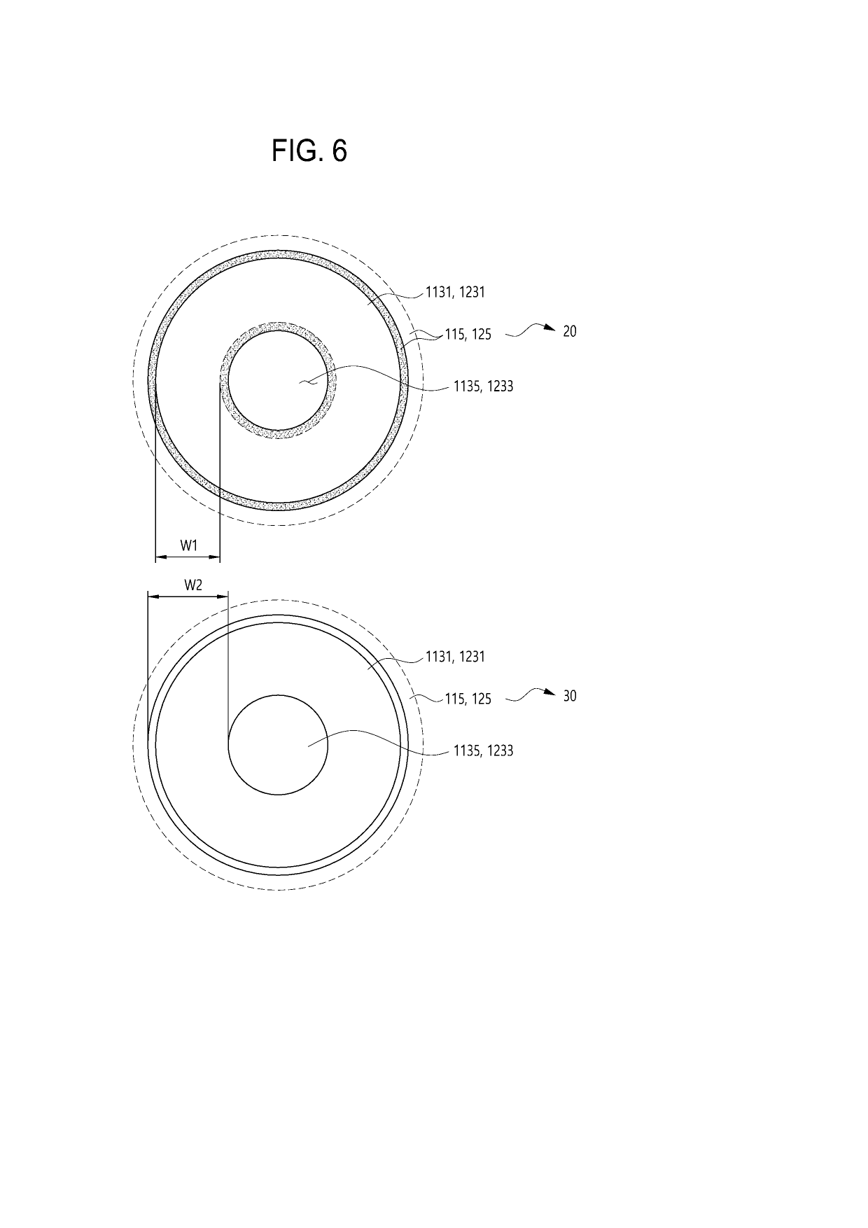

FIG. 6 is a view illustrating an effective contact area according to a method for manufacturing fastening members of an electronic device case in accordance with example embodiments of the disclosure.

Referring to FIGS. 5A, 5B and 6, assuming that the diameter of the contact holes 1135 and 1233 is the first diameter D1, FIG. 6 compares a first example 20 in which the peeling target is set to be the same as the first diameter D1, and a second example 30 in which the peeling target is set to a second diameter D2 greater than the first diameter D1.

In the first example 20, a width W1 of exposed surfaces common to hollow body 1131 or 1231 around the contact holes 1135 and 1233 may be narrower than a width W2 of exposed surfaces common to hollow body 1131 or 1231 around the contact holes 1135 and 1233 in the second example 30, where the peeling target diameter may be greater.

Therefore, as shown in the second example 30, excellent contact characteristics may be ensured between the fastening members 113 and 123 without interference from the coating layers 115 and 125. In addition, the overall effective contact area between the fastening members 113 and 123 may be significantly increased.

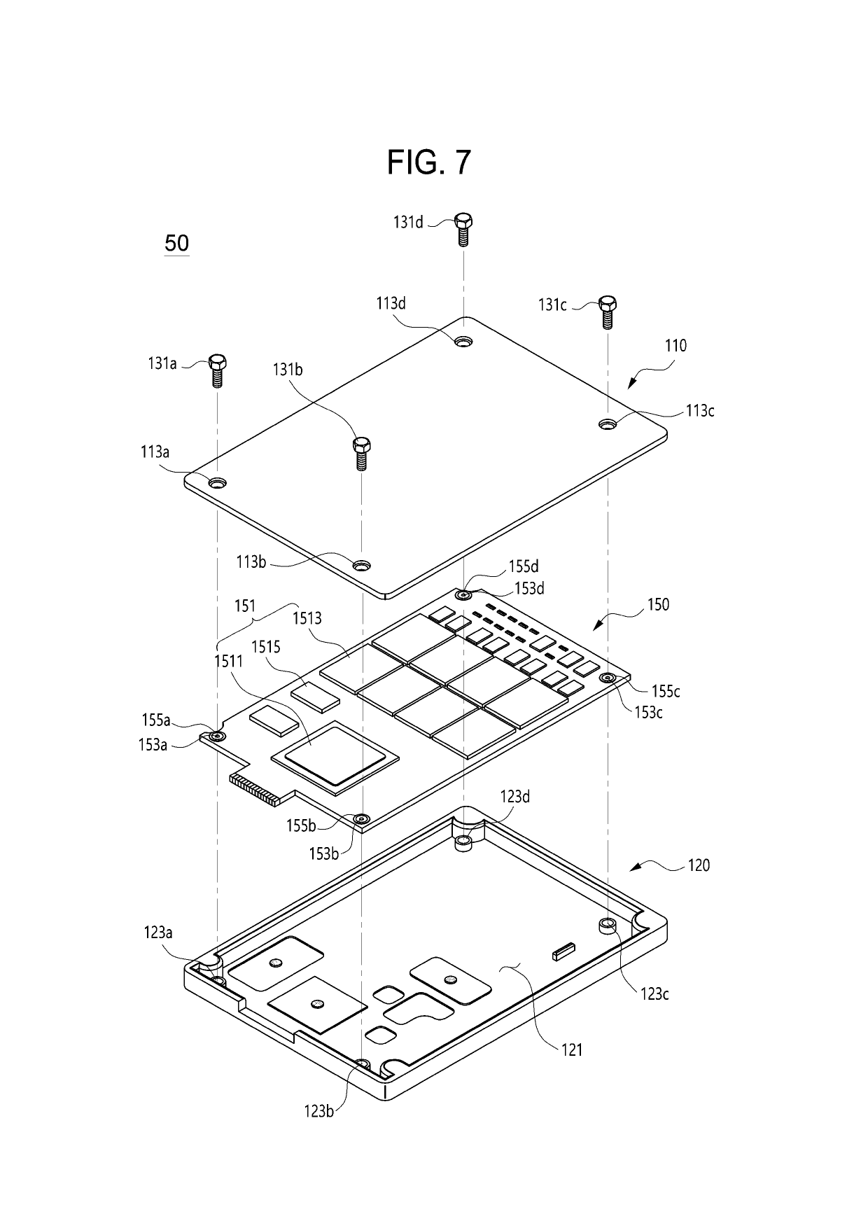

FIG. 7 is an exploded perspective view illustrating a storage device in accordance with example embodiments of the disclosure.

Referring to FIG. 7, a storage device 50 may include a PCB 150 received in an electronic device case (top case 110 and bottom case 120).

Electronic components 151 may be mounted on the PCB 150. Fastening holes 153a, 153b, 153c and 153d may be provided at respective corners of the PCB 150 at positions corresponding to first fastening members 113a, 113b, 113c and 113d of top case 110 and second fastening members 123a, 123b, 123c and 123d of bottom case 120. Grounding terminals 155a, 155b, 155c and 155d surrounding the fastening holes may be formed around the respective fastening holes.

In example embodiments, the electronic components 151 mounted on the PCB 150 may include a controller 1511, a non-volatile memory device 1513 and a volatile memory device 1515.

The PCB 150 may be mounted such that the second fastening members 123a, 123b, 123c and 123d of the bottom case 120 align with through the fastening holes 153a, 153b, 153c and 153d. The top case 110 may be arranged such that the first fastening members 113a, 113b, 113c and 113d may contact the second fastening members 123a, 123b, 123c and 123d of the bottom case 120, and screws 131a, 131b, 131c and 131d may be fastened through the first and second fastening members.

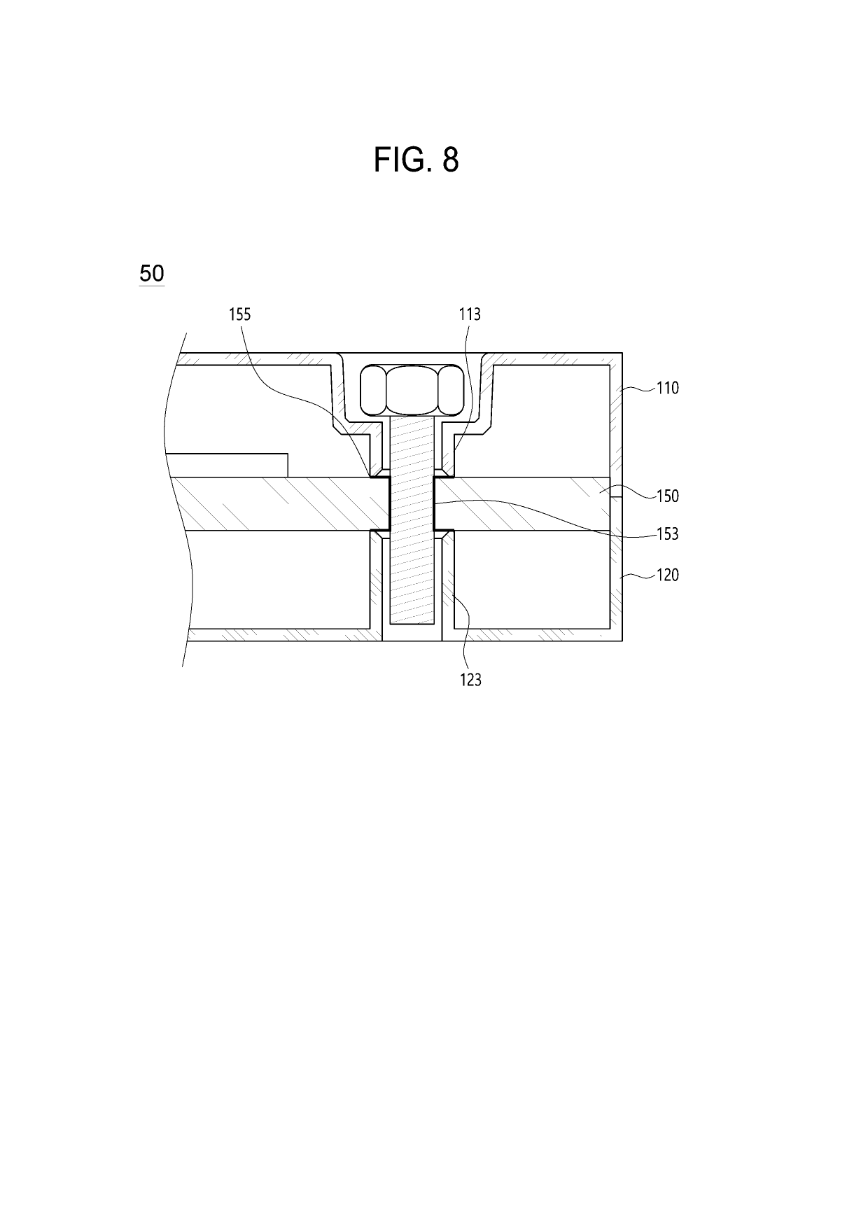

FIG. 8 is a partial cross-sectional view illustrating a storage device in accordance with example embodiments of the disclosure.

Referring to FIG. 8, a storage device 50 may be configured such that a PCB 150 may be received in an electronic device case 10 that includes a top case 110 and bottom case 120.

A fastening hole 153 (i.e., any of 153a, 153b, 153c and 153d) of the PCB 150 may be fastened to the fastening members 113 of the top case 110 and the fastening members 123 of the bottom case 120.

Since surfaces common to the contact holes of the first fastening members 113 and the second fastening members 123 may be exposed without shielding by the coating layers 115 and 125, the first and second fastening members may more effectively contact the grounding terminals 155 provided around the fastening hole 153 of the PCB 150 to dissipate ESD.

As described above, it will be understood by those skilled in the art that the present disclosure may be implemented in other specific forms without changing the technical idea or essential features. Therefore, the above-described embodiments should be understood as illustrative in all respects and not as restrictive. The scope of the present invention should be indicated by the appended claims rather than the foregoing detailed description, and all modifications or alterations derived from the meanings and scope of the claims and their equivalents should be construed as being included in the scope of the present invention.

What is claimed is:

1. A case for an electronic device, the case comprising:
a top case configured to cover a front surface of a printed circuit board (PCB) on which electronic components are mounted, the top case having first fastening members at respective corners of the top case; and
a bottom case receiving the PCB to cover a rear surface of the PCB, the bottom case having second fastening members at positions corresponding to the first fastening members,
wherein each of the top case and the bottom case includes a coating layer except for areas of interface between the first fastening members and the second fastening members.

2. The case of claim 1, wherein the first fastening members and the second fastening members are each configured in a form of a boss.

3. The case of claim 1, wherein the top case including the first fastening members and the bottom case including the second fastening members are formed of a conductive material.

4. The case of claim 1, wherein the first fastening members comprises a portion of the top case shaped to provide:
a hollow body;
a screw inlet hole at one end of the first fastening members configured to receive a screw inserted from outside of the top case; and
a screw outlet hole at the other end of the first fastening members configured to receive the screw inserted through the screw inlet hole,
wherein the other side of the body has a first diameter, and a surface exposed by removing the coating layer using a peeling target set to a second diameter larger than the first diameter is included.

5. The case of claim 4, wherein the second diameter is about 120% to about 130% of the first diameter.

6. The case of claim 1, wherein the second fastening members comprises a portion of the bottom case shaped to provide:
a hollow body; and
a screw inlet hole at one end of the second fastening members that receives a screw from the first fastening members,
wherein, the one side of the body has a third diameter, and a surface exposed by removing the coating layer using a peeling target set to a fourth diameter larger than the first diameter is included.

7. The case of claim 6, wherein the fourth diameter is about 120% to about 130% of the third diameter.

8. A method of fabricating an electronic device case, the method comprising:
providing a conductive material;
casting a top case having first fastening members and a bottom case having second fastening members using the conductive material;
forming a coating layer on each of the top case and the bottom case including surfaces of the first and second fastening members; and
removing the coating layer from surfaces of the first fastening members and the second fastening members in areas that contact each other.

9. The method of claim 8, wherein from a plan view, an area of contact has a first diameter and removing the coating layer comprises peeling the coating layer using a peeling target set to a second diameter larger than the first diameter.

10. The method of claim 8, wherein further comprising attaching at least one thermal interface material (TIM) pad to each of the top case and the bottom case.

11. A storage device comprising:
a printed circuit board (PCB) having electronic components, including a controller and a non-volatile memory device, mounted on a front surface of the PCB and having fastening holes at respective corners of the PCB;
a top case covering the front surface of the PCB and having first fastening members at positions corresponding to the fastening holes; and
a bottom case receiving the PCB to cover a rear surface of the PCB, and having second fastening members at positions corresponding to the first fastening members,
wherein each of the top case and the bottom case includes a coating layer except for areas of interface between the first fastening members and the second fastening members.

12. The storage device of claim 11, wherein the first fastening members and the second fastening members are each configured as a boss.

13. The storage device of claim 11, wherein the top case including the first fastening members and the bottom case including the second fastening members include a conductive material.

14. The storage device of claim 11, wherein the first fastening members comprises
a portion of the top case shaped to provide:
a hollow body;
a screw inlet hole at one end of the first fastening members configured to receive a screw inserted from outside of the top case; and
a screw outlet hole at the other end of the first fastening members configured to receive the screw inserted through the screw inlet hole,
wherein the other side of the body has a first diameter, and a surface exposed by removing the coating layer using a peeling target set to a second diameter larger than the first diameter is included.

15. The storage device of claim 14, wherein the second diameter is about 120% to about 130% of the first diameter.

16. The storage device of claim 11, wherein the second fastening members comprises a portion of the bottom case shaped to provide:
a hollow body; and
a screw inlet hole at one end of the second fastening members that receives a screw from the first fastening members,
wherein the one side of the body has a third diameter, and a surface exposed by removing the coating layer using a peeling target set to a fourth diameter larger than the third diameter is included.

17. The storage device of claim 16, wherein the fourth diameter is about 120% to about 130% of the third diameter.
